(19) United States
(12) Patent Application Publication
(10) Pub. No.: US 2014/0326976 A1
(43) Pub. Date: Nov. 6, 2014

(54) ORGANIC ELECTROLUMINESCENT ELEMENT

(71) Applicant: CANON KABUSHIKI KAISHA, Tokyo (JP)

(72) Inventor: Tsutomu Shiratori, Tokyo (JP)

(21) Appl. No.: 14/334,414

(22) Filed: Jul. 17, 2014

Related U.S. Application Data
(63) Continuation of application No. 13/117,001, filed on May 26, 2011.

(30) Foreign Application Priority Data
May 31, 2010 (JP) 2010-123733

(51) Int. Cl. H01L 51/50; H01L 27/32

(52) U.S. Cl. CPC H01L 51/5028; H01L 27/32; H01L 51/5004; H01L 51/5016
USPC 257/40

(57) ABSTRACT

An organic compound layer includes a fluorescent light-emitting sub-layer, a phosphorescent light-emitting sub-layer, and an exciton generation sub-layer which is disposed therebetween and which generates excitons. The interface between the fluorescent light-emitting sub-layer and the exciton generation sub-layer serves as an energy barrier for carriers. Excitons are generated on the exciton generation sub-layer side of the interface therebetween.

### CROSS REFERENCE TO RELATED APPLICATIONS

This application is a Continuation of U.S. patent application Ser. No. 13/117,001 filed May 26, 2011, which claims priority to Japanese Patent Application No. 2010-123733 filed May 31, 2010, each of which are hereby incorporated by reference herein in their entireties.

### BACKGROUND OF THE INVENTION

1. Field of the Invention

The present invention relates to an organic electroluminescent (EL) element including a pair of electrodes and an organic compound layer which is disposed between the electrodes and which includes at least one light-emitting sub-layer.

2. Description of the Related Art

In recent years, many attempts have been made to develop light-emitting devices and display apparatuses including organic EL elements. In general, an organic EL element includes two electrodes and an organic compound layer which is disposed between the electrodes and which includes a light-emitting sub-layer. Examples of a luminescent material for use in the light-emitting sub-layer include fluorescent materials and phosphorescent materials.

In principle, the phosphorescent materials can be expected to have higher efficiency as compared to the fluorescent materials. Because excitons generated by the recombination of carriers include singlet excitons and triplet excitons and the ratio of the singlet excitons to the triplet excitons is 1:3. Organic EL elements using singlet excitons extract fluorescent light emitted by the transition of the singlet excitons to the ground state. The emission yield of the organic EL elements is 25%, which is the theoretical upper limit, with respect to the number of generated excitons. If phosphorescent light emitted by the transition of the triplet excitons to the ground state is extracted, an emission yield that is at least three times the emission yield of the organic EL elements can be expected. In combination with intersystem crossing, that is, the transition from a singlet state, which is high in energy, to a triplet state, an emission yield of 100%, which is four times the emission yield of the organic EL elements, can be expected. Therefore, attempts are being made to develop phosphorescent materials emitting blue light, green light, or red light.

Until now, any blue phosphorescent material with a practical life has not been obtained. This prevents the practical use of organic EL elements containing phosphorescent materials with good power efficiency in applications such as full-color displays and white illuminations.

In order to solve this problem, the following documents propose organic EL elements which use blue fluorescent materials and blue-to-red phosphorescent materials in combination and which can be expected to have an emission quantum yield of about 100% in principle: PCT Japanese Translation Patent Publication No. 2008-516440 and Yiru Sun et al., “Management of singlet and triplet excitons for efficient white organic light-emitting devices”, Nature, vol. 440, p. 908 (2006) (hereinafter referred to as Non-patent Document 1).

An organic EL element disclosed in Non-patent Document 1 is outlined below. In the organic EL element, a region doped with a fluorescent material and a region doped with a phosphorescent material are separately arranged in a host material layer serving as a light-emitting layer. Excitons are locally generated in the light-emitting layer by recombining carriers in the fluorescent material-doped region. This results in 25% singlet excitons and 75% triplet excitons. The singlet excitons transfer the energy thereof via the Forster mechanism to excite singlet excitons of the fluorescent material and therefore the fluorescent material is immediately deactivated to emit fluorescent light. In contrast, the triplet excitons cannot transfer the energy thereof via the Forster mechanism because of spin-forbidden transition and therefore diffuse in the host material layer to reach the phosphorescent material-doped region. The triplet excitons collide with molecules of the phosphorescent material to excite triplet excitons of the phosphorescent material via the Dexter mechanism. Thereafter, the phosphorescent material is deactivated to emit fluorescent light. This allows the generated excitons to contribute to light emission in high proportions.

The fluorescent material-doped region and the phosphorescent material-doped region are spaced from each other at a distance greater than the range of the Forster mechanism (the Forster radius). This prevents that singlet excitons of the fluorescent material are excited and then transfer the energy thereof to singlet excitons of the phosphorescent material or directly excite singlet excitons of the phosphorescent material from excitons generated in the fluorescent material-doped region and therefore can prevent the inhibition of fluorescence.

However, in the organic EL element disclosed in Non-patent Document 1, thermal deactivation processes without emission cannot be completely eliminated. This is because excitons are generated in the fluorescent material-doped region and therefore there is a certain probability that triplet excitons collide with the fluorescent material to excite triplet excitons of the fluorescent material via the Dexter mechanism before the triplet excitons diffuse into the phosphorescent material-doped region. The energy of the excited triplet excitons of the fluorescent material is lost in the form of heat like light-emitting layers containing conventional fluorescent materials.

Although the proportion of fluorescent triplet excitons can be reduced by reducing the dose of the fluorescent material, a reduction in the dose of the fluorescent material increases the probability that singlet excitons are deactivated without transferring the energy thereof to the fluorescent material. In the case of emitting white light, color components in a light band corresponding to the fluorescent material are reduced and therefore the chromaticity of white light is reduced. A high-triplet energy material can be used for doping instead of the fluorescent material to avoid trapping triplet excitons. However, this causes an increase in fluorescent singlet energy and therefore excitation is unlikely to occur, resulting in an increase in the probability that singlet excitons are deactivated without transferring the energy thereof to the fluorescent material.

### SUMMARY OF THE INVENTION

Aspects of the present invention provide an organic electroluminescent element which contains a fluorescent material and a phosphorescent material and which has high emission quantum yield.

Aspects of the present invention are characterized in that an organic electroluminescent element includes an anode, a cathode, and an organic compound layer disposed between the anode and the cathode. The organic compound layer includes a fluorescent light-emitting sub-layer, a phosphorescent light-emitting sub-layer, and an exciton generation sub-layer which is disposed between the fluorescent light-emitting sub-layer and the phosphorescent light-emitting sub-layer and which generates excitons. An interface serving as an energy barrier for carriers is present between the fluorescent light-emitting sub-layer and the exciton generation sub-layer. The carriers are accumulated on the exciton generation sub-layer side of the interface, so that excitons are generated.

According to aspects of the present invention, an organic EL element having good power efficiency and a long life can be provided. This enables a further reduction in power consumption.

Further features of the present invention will become apparent from the following description of exemplary embodiments with reference to the attached drawings.

### BRIEF DESCRIPTION OF THE DRAWINGS

FIG. 1 is a schematic sectional view of an organic EL element according to an embodiment of the present invention.

FIG. 2 is a schematic sectional view of an organic EL element according to another embodiment of the present invention.

FIG. 3 is a schematic sectional view of an organic EL element according to another embodiment of the present invention.

FIG. 4 is a schematic sectional view of an organic EL element obtained in a comparative example.

### DESCRIPTION OF THE EMBODIMENTS

Embodiments of the present invention will now be described with reference to the attached drawings.

An organic electroluminescent element (organic EL element) according to an embodiment of the present invention includes an anode, a cathode, and an organic compound layer disposed between the anode and the cathode. The organic compound layer includes a light-emitting region. The light-emitting region includes a fluorescent light-emitting sub-layer, a phosphorescent light-emitting sub-layer, and an exciton generation sub-layer disposed between the fluorescent light-emitting sub-layer and the phosphorescent light-emitting sub-layer. The exciton generation sub-layer emits no light and generates excitons. In the organic EL element, an interface serving as an energy barrier for carriers is present between the fluorescent light-emitting sub-layer and the exciton generation sub-layer and carriers are accumulated on the exciton generation sub-layer side of the interface, so that excitons are generated. Thus, the use of the organic EL element allows a light-emitting device which has a life longer than that of conventional one and a power consumption less than that of conventional one or a display apparatus displaying a high-quality image to be provided. The organic EL element can be used as a white element emitting white light of high chromaticity. The organic EL element is more advantageous than conventional elements containing pure phosphorescent materials because triplet-triplet annihilation is avoided and a reduction in quantum efficiency due to an increase in driving current density is prevented. Aspects of the present invention are applicable to elements emitting light of a single color.

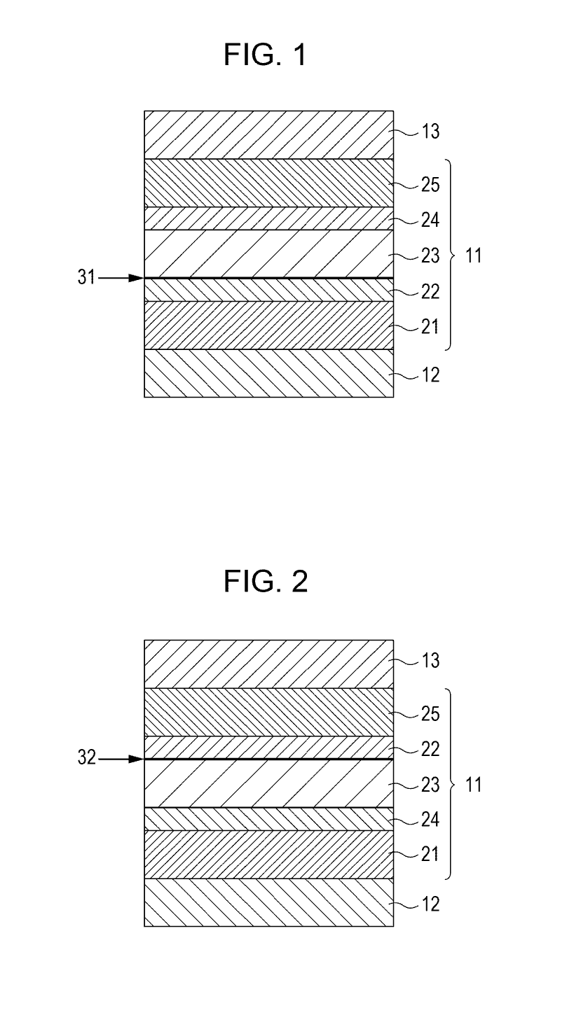

The organic EL element has, for example, a configuration shown in FIG. 1. The organic EL element includes an anode 12, a cathode 13, and an organic compound layer 11 disposed therebetween. One of the anode 12 and the cathode 13 is located on a light extraction side and is a transparent electrode and the other one is a transparent or reflective electrode. The term “reflective electrode” as used herein refers to not only an electrode made of a reflective material but also collectively refers to electrodes including conductive films made of a transparent conductive material such as indium tin oxide (ITO) or indium zinc oxide (IZO) and reflective thin-films which are disposed under the conductive films and which are made of a reflective metal. The organic compound layer 11 includes a hole transport sub-layer 21, a fluorescent light-emitting sub-layer 22, an exciton generation sub-layer 23, a phosphorescent light-emitting sub-layer 24, and an electron transport sub-layer 25, these sub-layers being arranged in that order. The organic compound layer 11 may further include a hole injection sub-layer disposed between the anode 12 and the hole transport sub-layer 21 and an electron injection sub-layer disposed between the cathode 13 and the electron transport sub-layer 25.

When a current is applied between the anode 12 and the cathode 13, holes and electrons are injected from the anode 12 and the cathode 13, respectively, into the exciton generation sub-layer 23 and are recombined with each other, whereby excitons are generated. A material for the fluorescent light-emitting sub-layer 22 and a material for the exciton generation sub-layer 23 are selected such that the interface 31 between the fluorescent light-emitting sub-layer 22 and the exciton generation sub-layer 23 serves as an energy barrier for electrons as described below. This allows electrons traveling in the exciton generation sub-layer 23 to be accumulated at the interface 31, resulting in the formation of an exciton generation region where most of the accumulated electrons are recombined with holes at sites located on the fluorescent light-emitting sub-layer 22 side in the exciton generation sub-layer 23.

Among the generated excitons, singlet excitons transfer the energy thereof to a fluorescent material doped in the fluorescent light-emitting sub-layer 22 via the Forster mechanism to excite fluorescent singlet excitons, thereby causing fluorescence. In contrast, triplet excitons cannot transfer the energy thereof to the fluorescent material because of spin-forbidden transition and diffuse via the Dexter energy-transfer mechanism to enter the phosphorescent light-emitting sub-layer 24 to excite phosphorescent triplet excitons, thereby causing phosphorescence. This allows the generated excitons to contribute to light emission without loss.

The triplet excitons can be effectively prevented from migrating into the fluorescent light-emitting sub-layer 22 in such a manner that the triplet excitation energy of the fluorescent light-emitting sub-layer 22 is set to be greater than the triplet excitation energy of the of exciton generation sub-layer 23.

In order to efficiently prevent excitons from being generated in the fluorescent light-emitting sub-layer 22, an exciton inhibition sub-layer (not shown) for preventing the formation of excitons may be placed between the fluorescent light-emitting sub-layer 22 and the exciton generation sub-layer 23. When the exciton inhibition sub-layer is present in the configuration shown in FIG. 1, the interface between the exciton inhibition sub-layer and the exciton generation sub-layer 23 serves as an energy barrier for electrons, which are accumulated at this interface, and an exciton generation region is formed near this interface. In the organic EL element shown in FIG. 1, excitons are generated in the exciton generation sub-layer 23, in which electrons are accumulated, some of the electrons pass through this interface and excitons can be possibly generated on the opposite side of this interface. Therefore, excitons are generated in the fluorescent light-emitting sub-layer 22, which leads to the excitation and thermal deactivation of triplet excitons of the fluorescent material. However, when the exciton inhibition sub-layer is placed between the fluorescent light-emitting sub-layer 22 and the exciton generation sub-layer 23 and the triplet excitation energy of the fluorescent light-emitting sub-layer 22 is greater than the triplet excitation energy of the of exciton generation sub-layer 23, triplet excitons generated in the exciton inhibition sub-layer diffuse into the exciton generation sub-layer 23 and therefore triplet excitons of the fluorescent material can be prevented from being excited.

When the triplet excitation energy of the fluorescent light-emitting sub-layer 22 is greater than that of the exciton inhibition sub-layer, the triplet excitons generated in the exciton inhibition sub-layer cannot enter the fluorescent light-emitting sub-layer 22 and therefore fluorescent triplet excitons can be securely prevented from being excited.

In the configuration shown in FIG. 1, materials are selected such that the interface 31 between the fluorescent light-emitting sub-layer 22 and the exciton generation sub-layer 23 serves as an energy barrier for electrons. The present invention is not limited to the configuration. The phosphorescent light-emitting sub-layer 24, the exciton generation sub-layer 23, and the fluorescent light-emitting sub-layer 22 may be arranged in that order as shown in FIG. 2 such that the interface 32 between the fluorescent light-emitting sub-layer 22 and the exciton generation sub-layer 23 serves as an energy barrier for holes. This configuration functions as well as the above configuration.

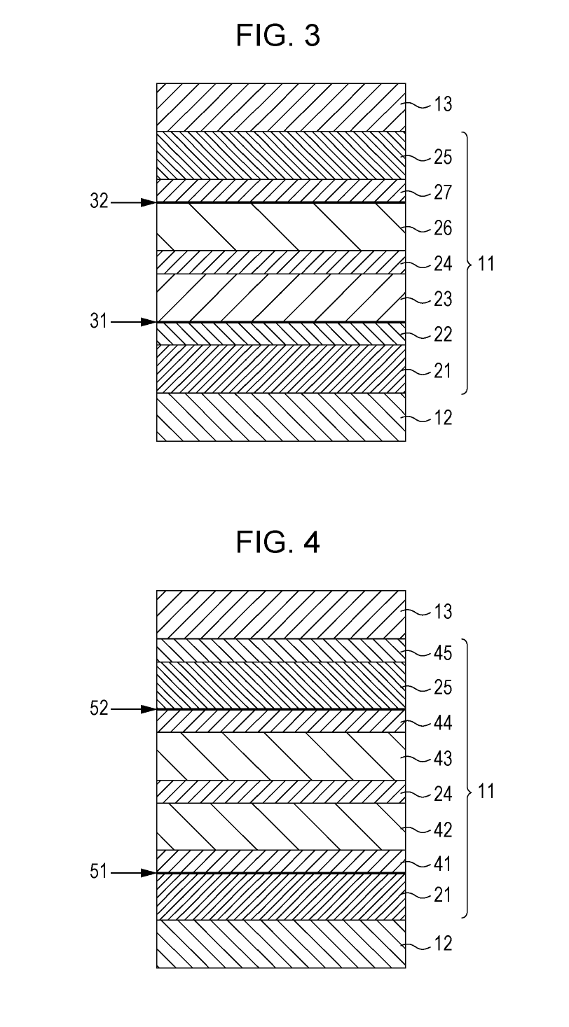

Alternatively, the fluorescent light-emitting sub-layer 22, the exciton generation sub-layer 23, the phosphorescent light-emitting sub-layer 24, a exciton generation sub-layer 26, and a fluorescent light-emitting sub-layer 27 may be arranged in that order as shown in FIG. 3. In this configuration, the interface 31 between the fluorescent light-emitting sub-layer 22, the exciton generation sub-layer 23 serves as an energy barrier for electrons and the interface 32 between the exciton generation sub-layer 26 and the fluorescent light-emitting sub-layer 27 serves as an energy barrier for holes.

According to aspects of the present invention, in order to prevent the excitation of singlet excitons of a phosphorescent material, exciton generation regions are intensively arranged near the interface 31 between the exciton generation sub-layer 23 and the fluorescent light-emitting sub-layer 22 and the interface 32 between the exciton generation sub-layer 26 and the fluorescent light-emitting sub-layer 27. The exciton generation regions may be spaced from the phosphorescent light-emitting sub-layer 24 at a distance not less than the Forster radius. When the concentration of the exciton generation regions is insufficient and excitons are generated at sites close to the phosphorescent light-emitting sub-layer 24, the energy of some of singlet excitons is transferred to the phosphorescent material and is dissipated. This may not be preferable because color components of light emitted from the phosphorescent material are reduced. Since excited phosphorescent singlet excitons transition to a triplet state via intersystem crossing to contribute to phosphorescence, the generated excitons can contribute to emit light without loss.

An organic compound used for each sub-layer of the above configuration is a low-molecular-weight material, a high-molecular-weight material, or a mixture thereof. An inorganic compound may optionally be used.

Examples of compounds usable for the organic compound layer 11 of the organic EL element are described below. The present invention is not limited to the examples below.

A hole-transporting material contained in the hole transport sub-layer 21 may readily inject holes from the anode 12 and may have good mobility to transport the injected holes to the light-emitting region. Examples of a low-molecular-weight material and high-molecular-weight material having hole injection/transport ability include, but are not limited to, triarylamine derivatives, phenylenediamine derivatives, triazole derivatives, oxadiazole derivatives, imidazole derivatives, pyrazoline derivatives, pyrazolone derivatives, oxazole derivatives, fluorenone derivatives, hydrazone derivatives, stilbene derivatives, phthalocyanine derivatives, porphyrin derivatives, and conductive polymers such as polyvinylcarbazole, polysilylene, and polythiophene. Specific examples thereof are as described below.

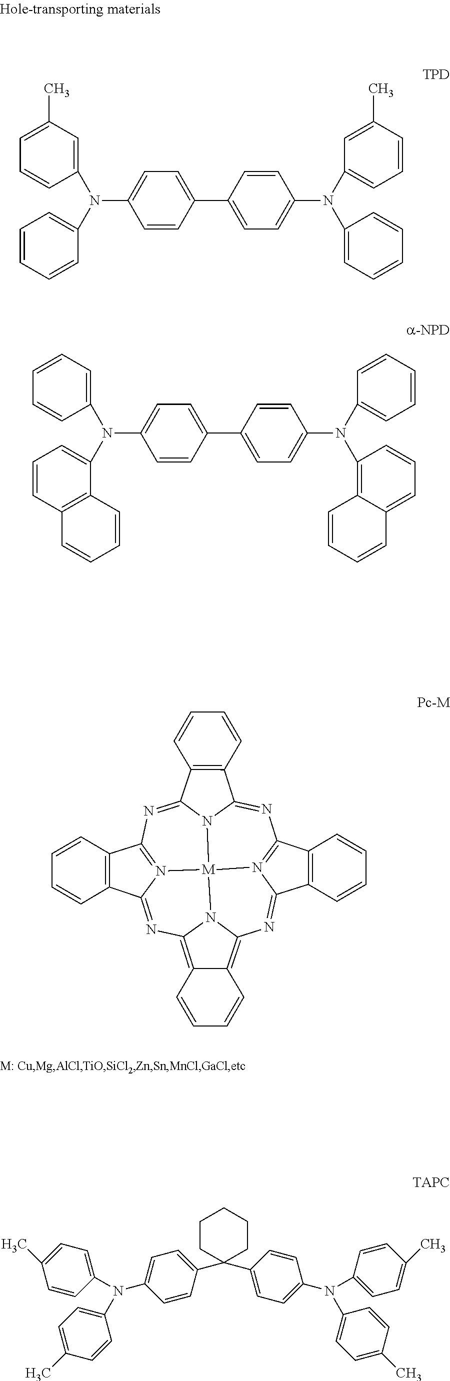

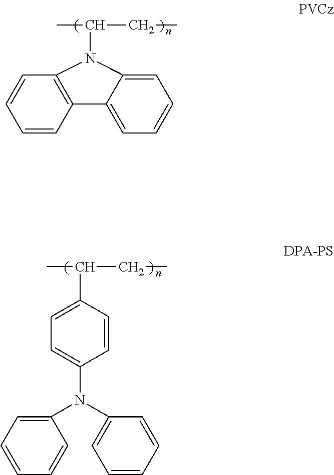

The fluorescent light-emitting sub-layers 22 and 27 and the phosphorescent light-emitting sub-layer 24, which make up the light-emitting region, may contain a host material slightly doped with the phosphorescent material and the phosphorescent material, respectively, which serve as dopants. In this case, the highest occupied molecular orbital (HOMO) energy level and lowest unoccupied molecular orbital (LUMO) energy level of each of the fluorescent light-emitting sub-layers 22 and 27 and the phosphorescent light-emitting sub-layer 24 are the HOMO energy level and LUMO energy level, respectively, of the host material. The exciton generation sub-layer 23, which is disposed between the fluorescent light-emitting sub-layer 22 and the phosphorescent light-emitting sub-layer 24, and the exciton generation sub-layer 26, which is disposed between the fluorescent light-emitting sub-layer 27 and the phosphorescent light-emitting sub-layer 24, may contain the same material as a host material contained in the phosphorescent light-emitting sub-layer 24. In order to form an energy barrier for carrier between the exciton generation sub-layers 23 and 26, the host material in the fluorescent light-emitting sub-layers 22 and 27 needs to be greatly different in LUMO or HOMO energy level from the exciton generation sub-layers 23 and 26. In particular, when a fluorescent light-emitting sub-layer is located more close to an anode than an exciton generation sub-layer, a material having a LUMO energy level less than the LUMO energy level of the exciton generation sub-layer is used for the fluorescent light-emitting sub-layer to form an energy barrier for electrons. When a fluorescent light-emitting sub-layer is located more close to a cathode than an exciton generation sub-layer, a material having a HOMO energy level less than the HOMO energy level of the fluorescent light-emitting sub-layer is used for the exciton generation sub-layer to form an energy barrier for electrons. The absolute value of the difference in HOMO energy level (LUMO energy level) therebetween may be 0.2 eV and such as 0.3 eV or more. The LUMO energy level and the HOMO energy level are expressed in absolute values. In order to prevent triplet excitons generated in the exciton generation sub-layers 23 and 26 from diffusing in the fluorescent light-emitting sub-layers 22 and 27, a material having a triplet excitation energy greater than that of the exciton generation sub-layers 23 and 26 may be used for the fluorescent light-emitting sub-layers 22 and 27. In the case of inserting an exciton generation sub-layer, the host material in the fluorescent light-emitting sub-layers 22 and 27 can be relatively freely selected if a material for the exciton generation sub-layer is selected so as to meet the above requirements.

According to aspects of the present invention, when the organic compound layer 11 has such a host-guest structure as described above, the HOMO and LUMO energy levels and excitation energy of the organic compound layer 11 are those of a host material. Examples of a material for each sub-layer making up the light-emitting region are as described below.

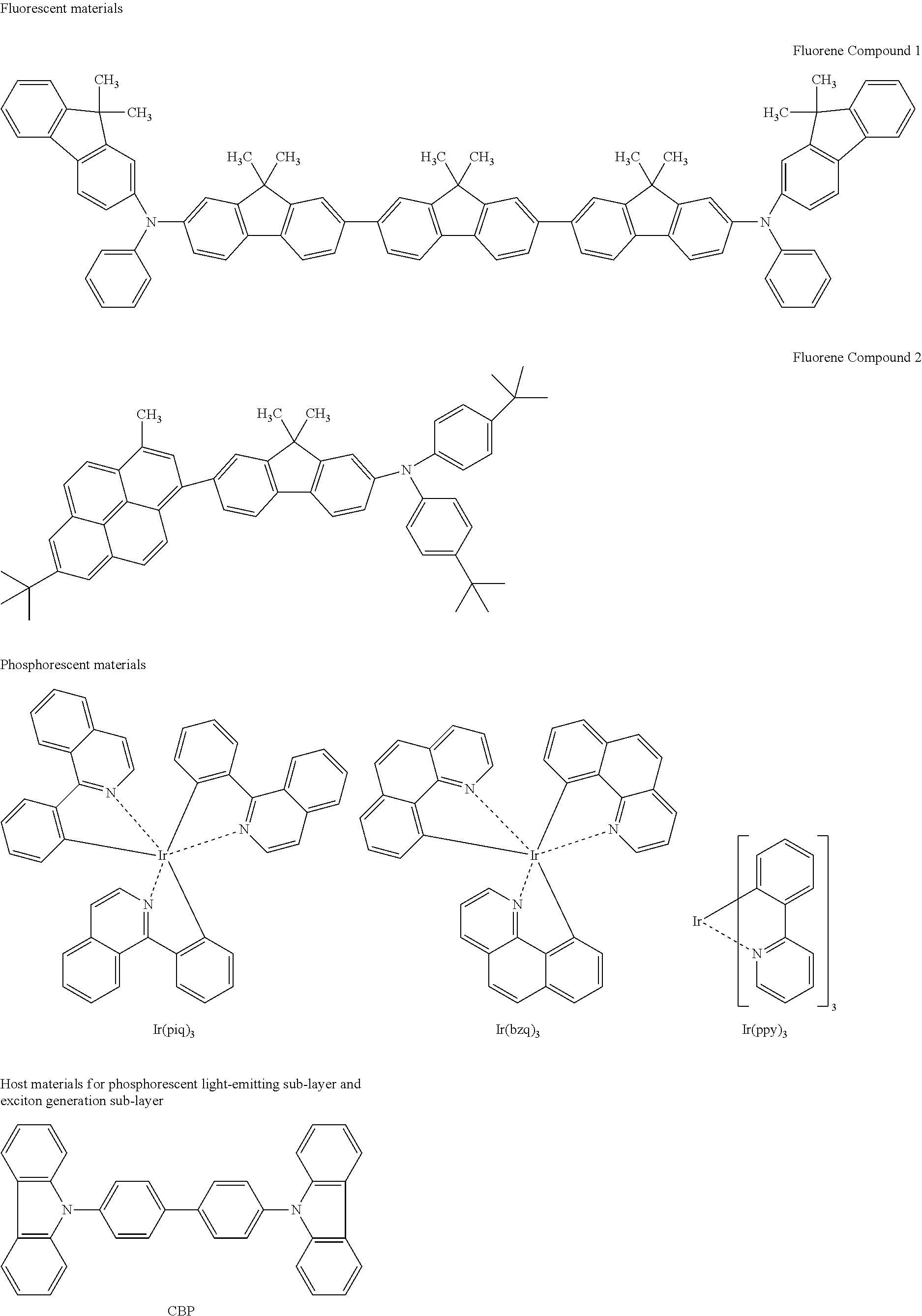

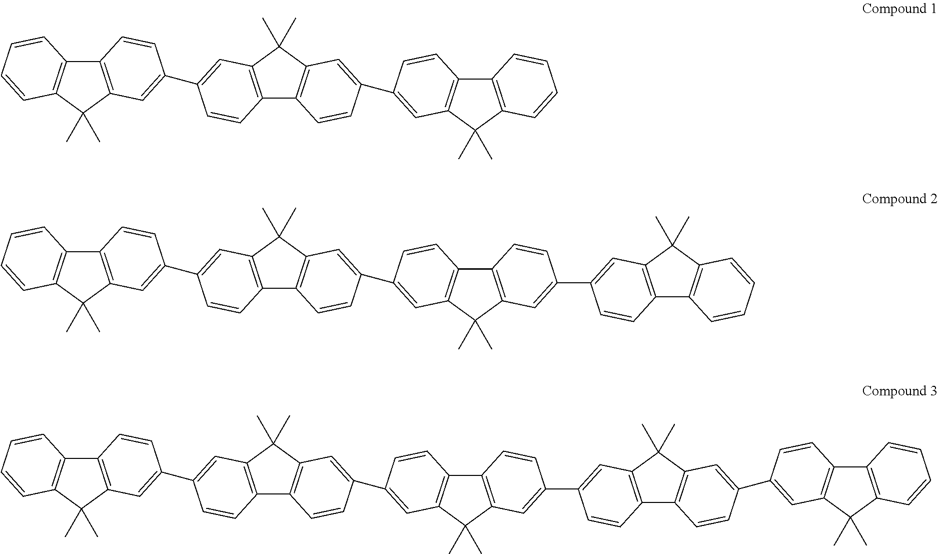

A host for the fluorescent light-emitting sub-layer 22 and a material for the exciton generation sub-layer 23 adjacent thereto are, for example, one similar to the hole-transporting material. A host for the fluorescent light-emitting sub-layer 27 and a material for the exciton generation sub-layer 26 adjacent thereto may be one similar to an electron-transporting material below.

The electron-transporting material is contained in the electron transport sub-layer 25. The electron-transporting material can be arbitrarily selected from materials having a function of transporting injected electrons to the light-emitting region and is selected in consideration of a balance with the carrier mobility of the hole-transporting material. Examples of the electron-transporting material include, but are not limited to, oxadiazole derivatives, oxazole derivatives, thiazole derivatives, thiadiazole derivatives, pyrazine derivatives, triazole derivatives, triazine derivatives, perylene derivatives, quinoline derivatives, quinoxaline derivatives, fluorenone derivatives, anthrone derivatives, phenanthroline derivatives, and organometallic complexes. Specific examples thereof are as described below.

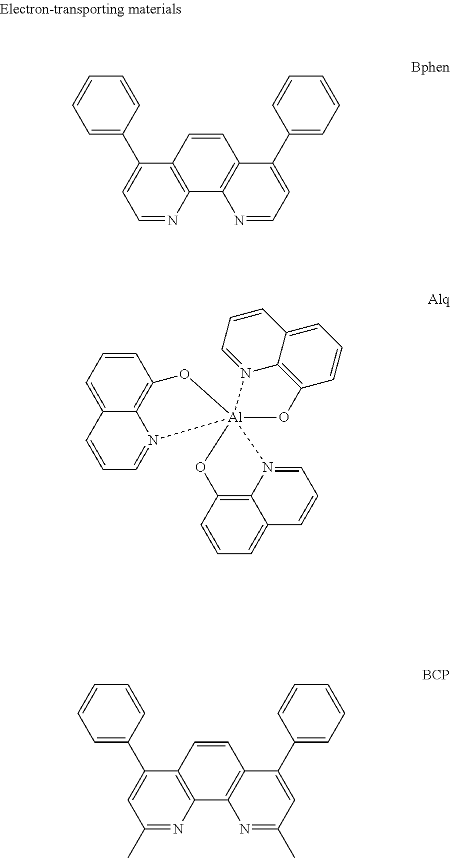

According to aspects of the present invention, when a hole injection sub-layer is disposed between the hole transport sub-layer 21 and the anode 12, examples of a hole-injecting material contained in the hole injection sub-layer include copper phthalocyanine (CuPc) and transition metal oxides such as MoO₃, WO₃, and V₂O₃. In one aspect of the present invention, when an electron injection sub-layer is disposed between the electron transport sub-layer 25 and the cathode 13, examples of an electron-injecting material contained in the electron injection sub-layer include alkali metals, alkaline-earth metals, and compounds containing these metals. Electron injection ability can be imparted to the electron-transporting material in such a manner that the electron-transporting material is doped with 0.1% to several tens of percent of the electron-injecting material on a mass basis. The electron injection sub-layer may not be essential and may have a thickness of about 10 nm to 100 nm in consideration of the damage caused during the formation of the cathode 13.

The organic compound layer 11 is usually formed by a vacuum vapor deposition process, an ionization vapor deposition process, a sputtering process, or a plasma process. The organic compound layer 11 can be formed by a known coating process such as a spin coating process, a dipping process, a casting process, a Langmuir-Blodgett (LB) process, or an ink jet process using a solution containing an appropriate solvent. Such a coating process can be used in combination with an appropriate binder resin to form the organic compound layer 11. The binder resin can be selected from various resins. Examples of the binder resin include, but are not limited to, polyvinylcarbazole resins, polycarbonate resins, polyester resins, polyallylate resins, polystyrene resins, ABS resins, polybutadiene resins, polyurethane resins, acrylic resins, methacrylic resins, butyral resins, polyvinyl acetal resins, polyamide resins, polyimide resins, polyethylene resins, polyethersulfone resins, diallyl terephthalate resins, phenol resins, epoxy resins, silicone resins, polysulfone resins, and urea resins. These resins may be used alone or in combination or may be used in the form of copolymers. The binder resin may be used in combination with a known additive such as a plasticizer, an oxidation inhibitor, or an ultraviolet absorber.

When the cathode 13 is transparent, a conductive oxide such as ITO or IZO can be used to form the cathode 13. Such a conductive oxide may be selected such that a combination of the electron transport sub-layer 25 and the electron injection sub-layer exhibits good electron injection ability. The cathode 13 can be formed by a sputtering process.

In one aspect of the present invention, a protective layer may be used for the purpose of avoiding the contact with oxygen or moisture. Examples of the protective layer include metal nitride films such as silicon nitride films and silicon oxynitride films; metal oxide films such as tantalum oxide films; diamond thin-films; polymer films such as fluorocarbon resin films, polyparaxylene films, polyethylene films, silicone films, and polystyrene films; and photocurable resin films. The organic EL element may be covered with glass, a gas impermeable film, or metal or may be packaged with an appropriate sealing resin. The protective layer may contain a moisture absorbent so as to have increased moisture resistance.

The anode 12 is located on a substrate side as described above. The cathode 13 may be located on the substrate side, which enables aspects of the present invention. Aspects of the present invention are not limited to such a configuration. The following structure enables the present invention: a bottom emission structure in which a transparent electrode, the organic compound layer 11, and a reflective electrode are arranged on a transparent substrate in that order. Furthermore, the anode 12 and the cathode 13 may be both transparent.

### EXAMPLES

Aspects of the present invention are further described below in detail with reference to examples. The present invention is not limited to the examples. The terms “HOMO” and “LUMO” as used hereinafter refer to the HOMO energy level and the LUMO energy level, respectively, which are expressed in absolute values.

### Example 1

An organic EL element, having a configuration shown in FIG. 3, including an electron injection sub-layer (not shown) disposed between a cathode 13 and an electron transport sub-layer 25 was prepared by a procedure below.

A layer of an Ag alloy (Ag—Pd—Cu) used as a reflective metal was formed on a glass substrate serving as a support by a sputtering process so as to have a thickness of about 100 nm and was then patterned. An ITO layer serving as a transparent conductive film was formed on the Ag alloy layer by a sputtering process so as to have a thickness of about 20 nm and was then patterned, whereby an anode 12 serving as a reflective electrode was formed. An isolation film was formed on the anode 12 using an acrylic resin, whereby an anode-bearing substrate was prepared. The anode-bearing substrate was ultrasonically cleaned with isopropyl alcohol (IPA), was boiled in IPA, and was then dried. After the anode-bearing substrate was cleaned with UV light and ozone, an organic compound layer 11 below and the cathode 13 were continuously formed in a vacuum chamber with a pressure of 1×10⁻⁴ Pa by resistive heating vacuum deposition.

After a hole transport sub-layer 21 was formed using TPD so as to have a thickness of 35 nm, a fluorescent light-emitting sub-layer 22 doped with 6% by mass of Fluorene Compound 1 was formed using TPD as a host material so as to have a thickness of 5 nm, Fluorene Compound 1 being a fluorescent material. After an exciton generation sub-layer 23 was formed using CBP so as to have a thickness of 15 nm, a phosphorescent light-emitting sub-layer 24 doped with 5% by mass of Ir(ppy)₃ was formed using CBP as a host material so as to have a thickness of 20 nm, Ir(ppy)₃ being a phosphorescent material. An exciton generation sub-layer 26 was formed using CBP so as to have a thickness of 15 nm. The reason why the same host material was used to form the hole transport sub-layer 21 and the fluorescent light-emitting sub-layer 22 was to reduce the energy barrier of holes at the interface between these two sub-layers.

After a fluorescent light-emitting sub-layer 27 doped with 6% by mass of Fluorene Compound 1 was formed using Bphen as a host material so as to have a thickness of 5 nm, an electron transport sub-layer 25 was formed using Bphen so as to have a thickness of 15 nm. Furthermore, an electron injection sub-layer (not shown) was formed by the co-deposition of Bphen and Cs₂CO₃ at a mass ratio of 90:10 so as to have a thickness of 20 nm. The reason why the same host material was used to form the electron transport sub-layer 25 and the fluorescent light-emitting sub-layer 27 was to reduce the energy barrier of holes at the interface between the two sub-layers.

The anode-bearing substrate having the electron injection sub-layer was moved to a sputtering system without breaking a vacuum. The cathode 13, which was transparent, was formed using ITO so as to have a thickness of 60 nm. Furthermore, a protective layer was formed using silicon oxynitride so as to have a thickness of 700 nm.

In the organic EL element, the LUMO of TPD of the fluorescent light-emitting sub-layer 22 is 2.30 eV and the LUMO of CBP of the exciton generation sub-layer 23 is 2.54 eV; hence, an energy barrier for electrons is present at the interface 31 therebetween. Therefore, electrons are accumulated on the exciton generation sub-layer 23 side of the interface 31 and carrier recombination occurs, so that excitons are generated. Most of the excitons are generated on the exciton generation sub-layer 23 side of the interface 31 and only a slight number of the excitons are generated in the fluorescent light-emitting sub-layer 22.

The HOMO of CBP of the exciton generation sub-layer 26 is 6.05 eV and the HOMO of Bphen of the fluorescent light-emitting sub-layer 27 is 6.48 eV; hence, an energy barrier for holes is present at the interface 32 therebetween. Therefore, holes are accumulated on the exciton generation sub-layer 26 side of the interface 32 and carrier recombination occurs, so that excitons are generated. Most of the excitons are generated on the exciton generation sub-layer 26 side of the interface 32 and substantially no excitons are generated in the fluorescent light-emitting sub-layer 27. Since the triplet excitation energy of Bphen is 2.59 eV and that of CBP is 2.56 eV, that is, Bphen is greater in triplet excitation energy than CBP, triplet excitons generated on the exciton generation sub-layer 26 side of the interface 32 cannot diffuse into the fluorescent light-emitting sub-layer 27.

Thus, in the organic EL element of Example 1, the generated triplet excitons are hardly consumed in exciting triplet excitons of the fluorescent material, diffuse in the exciton generation sub-layers 23 and 26, are efficiently consumed in exciting triplet excitons of the phosphorescent material, and therefore can contribute to light emission.

Singlet excitons generated in the exciton generation sub-layers 23 and 26 have a large Forster radius and therefore transfer the energy thereof to the fluorescent material to excite singlet excitons of the fluorescent material to contribute to light emission. Since phosphorescent material is spaced from an exciton generation region located near the interface therebetween, no singlet excitation due to Forster transfer occurs.

### Comparative Example 1

In Comparative Example 1, an organic EL element including an exciton generation region doped with a fluorescent material was prepared by a procedure below.

TPD was deposited on an anode-bearing substrate treated as described in Example 1, whereby a hole transport sub-layer 21 with a thickness of 40 nm was formed. A fluorescent light-emitting sub-layer 41 doped with 4% by mass of Fluorene Compound 1 was formed using CBP as a host material so as to have a thickness of 5 nm, Fluorene Compound 1 being a fluorescent material. A spacer sub-layer 42 for separating the exciton generation region from a phosphorescent light-emitting sub-layer 24 was formed using CBP so as to have a thickness of 10 nm. The phosphorescent light-emitting sub-layer 24 was formed using CBP as a host material so as to have a thickness of 20 nm and was doped with 5% by mass of Ir(ppy)₃, which was a phosphorescent material. A spacer sub-layer 43 was formed using CBP so as to have a thickness of 10 nm. A fluorescent light-emitting sub-layer 44 doped with 4% by mass of Fluorene Compound 1 was formed using CBP as a host material so as to have a thickness of 5 nm.

An electron transport sub-layer 25 was formed using Bphen so as to have a thickness of 20 nm. Furthermore, an electron injection sub-layer 45 was formed by the co-deposition of Bphen and Cs₂CO₃ at a mass ratio of 90:10 so as to have a thickness of 20 nm. The anode-bearing substrate having the electron injection sub-layer 45 was moved to a sputtering system without breaking a vacuum. A transparent cathode 13 was formed using ITO so as to have a thickness of 60 nm. Furthermore, a protective layer was formed using silicon oxynitride so as to have a thickness of 700 nm.

In the organic EL element, the LUMO of TPD of the hole transport sub-layer 21 is 2.30 eV and the LUMO of CBP of the fluorescent light-emitting sub-layer 41 is 2.54 eV; hence, an energy barrier for electrons is present at the interface 51 therebetween. Therefore, electrons are accumulated on the fluorescent light-emitting sub-layer 41 side of the interface 51 and carrier recombination occurs, so that excitons are generated. That is, excitons are generated in the fluorescent light-emitting sub-layer 41.

The HOMO of CBP of the fluorescent light-emitting sub-layer 44 is 6.05 eV and the HOMO of Bphen of the electron transport sub-layer 25 is 6.48 eV; hence, an energy barrier for holes is present at the interface 52 therebetween. Therefore, electrons are accumulated on the fluorescent light-emitting sub-layer 44 side of the interface 52 and carrier recombination occurs, so that excitons are generated. That is, excitons are generated in the fluorescent light-emitting sub-layer 44.

In the organic EL element, most of triplet excitons generated in the fluorescent light-emitting sub-layers 41 and 44 are consumed in exciting triplet excitons of the fluorescent material and are thermally deactivated without contributing to light emission.

In the organic EL element of each of Example 1 and Comparative Example 1, the change in external quantum efficiency thereof was measured with respect to the dose of a guest added to a fluorescent light-emitting sub-layer, whereby an advantage according to aspects of the present invention was confirmed as described below.

In the organic EL element of Example 1, an increase in the dose of the guest added increased the brightness of a blue component of fluorescent light, the external quantum efficiency thereof peaked at a dose of about 5% to 10% by mass, and a further increase in the dose thereof reduced the external quantum efficiency. The brightness of a green component of phosphorescent light was constant independently of the dose of the guest added.

In the organic EL element of Comparative Example 1, the brightness of a green component of phosphorescent light decreased prior to the effect of concentration quenching in the fluorescent light-emitting sub-layer and the external quantum efficiency decreased when the dose of the guest added to the fluorescent light-emitting sub-layer was about 3% to 4% by mass. This is because triplet excitons generated in the fluorescent light-emitting sub-layer are consumed in exciting triplet excitons of the doped fluorescent material in increased proportions and contribute to excite the phosphorescent material in reduced proportions.

In the comparison between the organic EL element of Example 1 and that of Comparative Example 1 on the basis of a dose sufficient to achieve the maximum external quantum efficiency, the organic EL element (6% by mass) of Example 1 had a larger blue component of fluorescent light, a larger green component of phosphorescent light, and higher external quantum efficiency as compared to the organic EL element (4% by mass) of Comparative Example 1.

### Example 2

An organic EL element was prepared in substantially the same manner as that described in Example 1 except that an exciton inhibition sub-layer with a thickness of 2 nm was formed between a fluorescent light-emitting sub-layer 22 and an exciton generation sub-layer 23 using TAPC.

In the organic EL element, the LUMO of TAPC of the exciton inhibition sub-layer is 1.86 eV and the LUMO of CBP of the exciton generation sub-layer 23 is 2.54 eV. Therefore, an energy barrier for electrons is present at the interface between the exciton inhibition sub-layer and the exciton generation sub-layer 23. Electrons are accumulated on the exciton generation sub-layer 23 side of the interface and carrier recombination occurred, so that excitons are generated. Some of the accumulated electrons pass through the interface and therefore excitons are generated in a region on the exciton inhibition sub-layer side of the interface. However, this does not lead to the excitation or thermal deactivation of fluorescent triplet excitons because the region is not dope with the fluorescent material.

The triplet excitation energy of TAPC for the exciton inhibition sub-layer is 2.87 eV and the triplet excitation energy of CBP for the exciton generation sub-layer 23 is 2.56 eV. Therefore, triplet excitons generated in a region, present in the exciton inhibition sub-layer, close to the interface diffuse into the exciton generation sub-layer 23, which is low in energy, and hardly diffuse into the fluorescent light-emitting sub-layer 22. Thus, a process in which generated excitons are thermally deactivated by the excitation of fluorescent triplet excitons can be more securely blocked as compared to the organic EL element of Example 1. This allows the organic EL element of this example to have higher external quantum efficiency as compared to the organic EL element of Example 1.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-123733 filed May 31, 2010, which is hereby incorporated by reference herein in its entirety.

What is claimed is:

1. An organic electroluminescent element comprising:
a pair of opposing electrodes comprising an anode and a cathode;
a fluorescent light-emitting layer;
an organic compound layer comprising an organic compound; and
a phosphorescent light-emitting layer,
wherein the fluorescent light-emitting layer, the organic compound layer and the phosphorescent light-emitting layer are disposed between the pair of electrodes,
wherein the organic compound layer does not emit light and is disposed between the fluorescent light-emitting layer and the phosphorescent light-emitting layer in a direction in which the pair of electrodes are opposed to each other,
wherein the fluorescent light-emitting layer comprises a fluorescent guest material which is an organic compound emitting fluorescent light and a host material which is an organic material,
wherein the phosphorescent light-emitting layer comprises a phosphorescent guest material which is an organic compound emitting phosphorescent light and a host material which is an organic material,
wherein the fluorescent guest material emits light having a color different from a color of light emitted from the phosphorescent guest material,
wherein the organic compound layer is in contact with the fluorescent light-emitting layer,
wherein, when the fluorescent light-emitting layer is disposed at a side of the anode than the organic compound layer, an absolute value of LUMO of the organic compound of the organic compound layer is larger than an absolute value of LUMO of the host material of the fluorescent light-emitting layer, and a value obtained by subtracting the absolute value of the LUMO of the host material of the fluorescent light-emitting layer from the absolute value of the LUMO of the organic compound of the organic compound layer is 0.2 eV or more; and
wherein, when the fluorescent light-emitting layer is disposed at a side of the cathode than the organic compound layer, an absolute value of HOMO of the organic compound of the organic compound layer is smaller than an absolute value of HOMO of the host material of the fluorescent light-emitting layer, and a value obtained by subtracting the absolute value of the HOMO of the host material of the fluorescent light-emitting layer from the absolute value of the HOMO of the organic compound of the organic compound layer is 0.2 eV or more.

2. The organic electroluminescent element according to claim 1, further comprising another organic compound layer which is different from the organic compound layer, said another organic compound layer being disposed between the fluorescent light-emitting layer and the phosphorescent light-emitting layer and between the organic compound layer and the phosphorescent light-emitting layer, and being in contact with the organic compound layer.

3. The organic electroluminescent element according to claim 1, wherein the phosphorescent guest compound is an Ir complex.

4. The organic electroluminescent element according to claim 1, wherein the phosphorescent guest compound is Ir(ppy)3.

5. The organic electroluminescent element according to claim 1, wherein the phosphorescent guest compound is Ir(piq)3.

6. The organic electroluminescent element according to claim 1, wherein the fluorescent guest compound is a fluorene compound.

7. The organic electroluminescent element according to claim 1, wherein the organic compound of the organic compound layer is CBP.

8. The organic electroluminescent element according to claim 1, wherein the host compound of the phosphorescent light-emitting layer is CBP.

9. The organic electroluminescent element according to claim 1, wherein the host compound of the phosphorescent light-emitting layer is a fluorene compound.

10. An apparatus comprising the organic electroluminescent element according to claim 1 and a transparent substrate and having a bottom emission structure.

11. A display apparatus comprising the organic electroluminescent element according to claim 1.

12. A display apparatus comprising the organic electroluminescent element according to claim 1 and a transparent substrate and having a bottom emission structure.
